(19) United States
(12) Patent Application Publication
(10) Pub. No.: US 2026/0098892 A1
(43) Pub. Date: Apr. 9, 2026

(54) ELECTRONIC CIRCUIT

(71) Applicant: STMicroelectronics International N.V., Geneva (CH)

(72) Inventors: Bruno LEDUC, Voiron (FR); Sebastien DEDIEU, La Terrasse (FR); Jimmy FORT, Puyloubier (FR)

(73) Assignee: STMicroelectronics International N.V., Geneva (CH)

(21) Appl. No.: 19/351,410

(22) Filed: Oct. 7, 2025

(30) Foreign Application Priority Data
Oct. 9, 2024 (FR) FR2410916

(51) Int. Cl. G01R 31/26; H03K 17/687

(52) U.S. Cl. CPC G01R 31/2621; H03K 17/6872

(57) ABSTRACT

An electronic circuit includes a first circuit to be tested and a second circuit coupled to the first circuit and having at least components similar to those of the first circuit. The electronic circuit operates to: adopt a first state in which a determination of at least one indicator of aging of the first circuit is performed by measuring a value of the indicator using the second circuit, and then adopt a second state in which the first circuit is subjected to operating conditions causing aging, and then adopt the first state again. A comparison is then made of the determined values of the at least one indicator. The operation of the electronic circuit is then adapted according to the result of the comparison.

### PRIORITY CLAIM

This application claims the priority benefit of French Application for Patent No. FR2410916, filed on Oct. 9, 2024, the content of which is hereby incorporated by reference in its entirety to the maximum extent allowable by law.

### TECHNICAL FIELD

The present disclosure generally concerns electronic circuits and, in particular, electronic circuits forming part of near-field communication (NFC) or of wireless charging (WLC) systems, as well as their operating methods.

### BACKGROUND

NFC systems, or more generally systems implementing a wireless charging, use powers which become more and more significant as charging times are desired to be decreased.

This causes, in particular, the aging of amplifier elements in these systems.

There exists a need to measure this aging in order, for example, to take measures to preserve systems.

There is a need in the art to overcome all or part of the disadvantages of known circuits.

### SUMMARY

An embodiment provides an electronic circuit, comprising: a first circuit to be tested; a second circuit having at least components similar to those of the first circuit and coupled to the first circuit; the electronic circuit being configured to: adopt a first state in which a determination of at least one indicator of aging of the first circuit is performed by using the second circuit; then adopt a second state in which the first circuit is subjected to operating conditions causing aging; then adopt the first state again; compare determined values of the at least one indicator; and adapt operation of the electronic circuit according to a result of the comparison.

An embodiment provides an operating method of an electronic circuit comprising a first circuit to be tested, a second circuit similar to the first circuit and coupled to the first circuit, the method comprising the following steps: placing the electronic circuit in a first state in which a determination of at least one indicator of aging of the first circuit is carried out by using the second circuit; then placing the electronic circuit in a second state in which the first circuit is subjected to operating conditions causing aging; then placing the electronic circuit back in the first state; comparing the determined values of the at least one indicator; and adapting operation of the electronic circuit according to a result of the comparison.

According to an embodiment, when the comparison indicates aging of the first circuit, then performances of the electronic circuit are lowered.

According to an embodiment, the first and second circuits comprise at least one transistor, said at least one indicator being a threshold voltage of said at least one transistor.

According to an embodiment, in the second state, the second circuit is not subjected to said operating conditions causing aging.

According to an embodiment: the first circuit comprises a first transistor of NMOS type in series with a second transistor of PMOS type, a first conduction node of the second transistor being configured to be coupled to a first voltage rail set to a first reference voltage, a control node of the second transistor being connected to the junction point of the first and second transistors; the second circuit comprises a third transistor of NMOS type in series with a fourth transistor of PMOS type, a conduction node of the fourth transistor being configured to be coupled to the first voltage rail; the first and third transistors each having a conduction node coupled to ground.

In an embodiment, the first and third transistors are paired and the second and fourth transistors are paired.

In an embodiment, the second circuit comprises: a fifth transistor of PMOS type and having a conduction node configured to be coupled to the first voltage rail; and a sixth transistor of NMOS type with a conduction node coupled to ground and another conduction node coupled to its control node, the control node of the fifth transistor being connected to the control node of the fourth transistor, a first switch coupling a conduction node of the fifth transistor to a conduction node of the sixth transistor, a second switch coupling the control node of the fourth transistor to the junction point of the third and fourth transistors, a third switch coupling the control node of the fourth transistor to the first voltage rail.

In an embodiment, the second circuit comprises: a seventh transistor of PMOS type and having a conduction node configured to be coupled to the first voltage rail; and an eighth transistor of NMOS type and having a conduction node coupled to ground, a fourth switch coupling a conduction node of the seventh transistor to a conduction node of the eighth transistor, a fifth switch coupling ground to the control node of the sixth and eighth transistors, a sixth switch coupling the control nodes of the second and seventh transistors, a seventh switch coupling the control node of the seventh transistor to the first voltage rail.

In an embodiment, a ninth transistor is mounted in a cascode assembly to the first transistor.

In an embodiment, the second circuit comprises: a tenth transistor of PMOS type having a first conduction node coupled to the first voltage rail, having a control node coupled to the control node of the second transistor, and having a second conduction node coupled to its control node via an eighth switch; an eleventh transistor of NMOS type having a conduction node coupled to ground, another conduction node coupled to the second conduction node of the eleventh transistor via a ninth switch, and a control node configured to be coupled to a second voltage rail set to a second voltage; and a twelfth transistor of NMOS type having a first conduction node coupled to ground, having a second conduction node coupled to the second conduction node of the tenth transistor via a tenth switch, and having a control node coupled to the control node of the sixth transistor.

In an embodiment, the second circuit comprises a thirteenth transistor of PMOS type having a control node coupled to the control node of the eleventh transistor, a conduction node coupled to the first voltage rail, and another conduction node coupled to the junction point of the first and second transistors via an eleventh switch; and a twelfth switch coupling the junction point of the first and second transistors and a second conduction node of the second transistor.

In an embodiment: in the first state, the first and second switches are on and the third and fifth switches are off, the control node of the third transistor being coupled to a third voltage rail configured to receive a voltage ramp, and the control node of the first transistor being coupled to the second voltage rail; and in the second state, the first and second switches are off and the third and fifth switches are on, the control node of the third transistor being coupled to ground and the control node of the first transistor being coupled to the second voltage rail.

In an embodiment: in the first state, the fourth and sixth switches are on, and the seventh switch is off; and in the second state, the fourth and sixth switches are off, and the seventh switch is on.

In an embodiment: in the first state, the eighth and ninth switches are off and the tenth switch is on, and in the second state, the eighth and ninth switches are on and the tenth switch is off.

In an embodiment: in the first state, the eleventh switch is off and the twelfth switch is on, and in the second state, the eleventh switch is on and the twelfth switch is off.

In an embodiment, in the second state, the second circuit is also subjected to said operating conditions causing aging.

In an embodiment: the first and second circuits each comprise a similar logical chain; an output node of the logical chain of the second circuit is coupled to an input node of this same logical chain via a thirteenth switch so as to form a ring oscillator when the thirteenth switch is on; an input node of the logical chain of the first circuit is coupled to the input node of the logical chain of the second circuit via a fourteenth switch; and the output node of the logical chain of the second circuit and an output node of the logical chain of the first circuit are coupled to a different load of equivalent value.

In an embodiment, the logical chain of the first and second circuits comprises an odd number of inverters, or of buffer circuits, in series.

In an embodiment, said indicator is a frequency or a time shift of the oscillator.

In an embodiment, in the first state, thirteenth switch is on and fourteenth switch is off; and in the second state, thirteenth switch is off and the fourteenth switch is on.

An embodiment provides a method of using the electronic circuit such as described above, comprising the use of the second circuit to determine the aging of the first circuit and adapt the operation of the electronic circuit as a function of the determined aging.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 very schematically shows a diagram of a wireless charging circuit;

FIG. 2 shows in the form of blocks an element of the circuit of FIG. 1;

FIG. 3 shows an operating method of a circuit of FIG. 2 according to an embodiment;

FIG. 4 shows an embodiment of a block of FIG. 2;

FIG. 5 shows an embodiment of a block of FIG. 2; and

FIG. 6 shows an embodiment of a block of FIG. 2.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

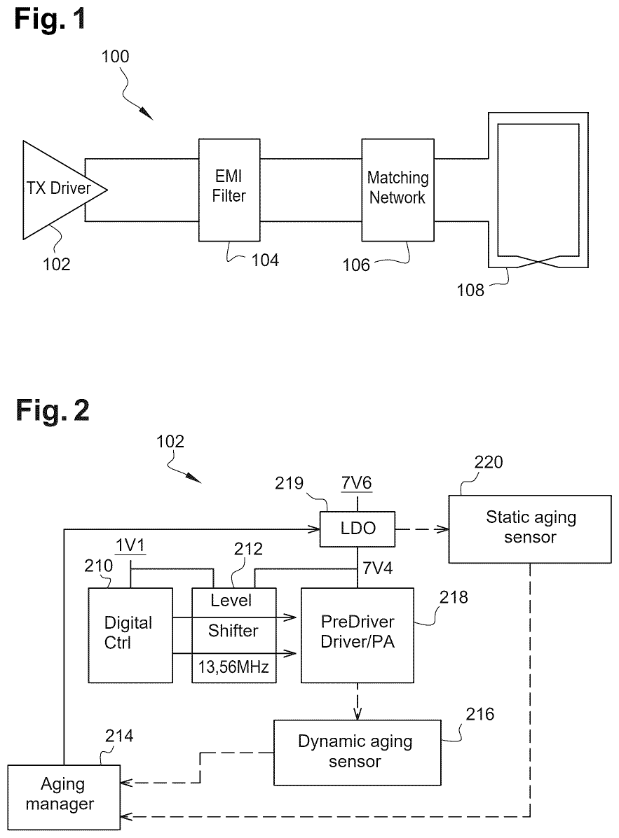

FIG. 1 very schematically shows a wireless charging or communication circuit 100.

The example of FIG. 1 is present, for example, in near-field communications (NFC) or wireless charging systems.

Circuit 100 comprises, for example, a transmission control circuit 102 (TX Driver) coupled, preferably connected, to a filtering stage 104 (EMI Filter). Filtering stage 104 is coupled, preferably connected, to an impedance matching circuit 106 (Matching Network), itself coupled, preferably connected, to an antenna 108.

Transmission control circuit 102 creates, for example, a +/− VDD differential square-wave or sinusoidal signal with a frequency of, for example, 13.56 MHz.

To increase the charging speed, the power emitted by antenna 108 may be increased. The current is defined by the antenna impedance and is at its maximum. It is thus necessary to increase the voltage across the terminals of the antenna.

In an example where the targeted power is in the order of a few watts, the working voltage VDD of transmission control circuit 102 is potentially increased to more than 7 Volts, which generates an increased aging of some of these components.

FIG. 2 shows in the form of blocks an element of the circuit of FIG. 1. More particularly, FIG. 2 illustrates an example of transmission control circuit 102.

The transmission control circuit 102 of FIG. 2 comprises a level shifter 212 (13.56 MHz) coupling a digital signal controller 210 (Digital Ctrl) to a control and amplification block 218 (PreDriver Driver/PA). Control and amplification block 218 is coupled, preferably connected, to a low dropout regulator 219 (LDO).

Digital signal controller 210 is coupled, preferably connected, to a voltage rail set for example to a 1.1 V voltage, and low dropout regulator 219 is coupled, preferably connected, to a voltage rail VDD set, for example, to a 7.6 V voltage. The operating voltage of block 218 is, for example, approximately 7.4 V. Such voltages cause aging, particularly in transistors or logical chains of control and amplifier block 218 and of low dropout regulator 219.

The aging of transistors, particularly of MOS transistors, may be of three types. A first type of aging (TDDB, time dependent dielectric breakdown) concerns the degradation of the gate oxide, a second type of aging (BTI, bias temperature instability) concerns defects all over the gate, and a third type of aging (HCl, hot carrier injection) resulting in defects located in the drain region due to the application of high voltages to the drain and the gate.

The impact of aging is reflected, in particular, in a variation in the threshold voltage of MOS transistors, but also in a variation in the current flowing through the drain and a current variation in the off state.

The embodiments bear on the provision of dynamic aging sensor circuits 216 and/or of static aging sensor circuits 220 respectively dedicated to the measurement of the aging of circuit components of block 218 and of block 219.

The dynamic aging sensor circuit 216 and the static aging sensor circuit 220 are coupled to aging control unit 214 which, depending on the aging measurements reported by circuits 216 and 220, will act on operating parameters of circuit 102. These operating parameters are, for example, a voltage, a current, or an operating frequency. If a predefined aging threshold is exceeded, one of the operating parameters can be decreased. This enables to ensure that the system operates less efficiently, but avoids a total degradation of system 100 and a loss of service.

In order to implement the dynamic aging measurement circuit 216 and/or the static aging measurement circuit 220, the embodiments provide an electronic circuit comprising: a first circuit to be tested; a second circuit having at least components similar to those of the first circuit and coupled to the first circuit; where the electronic circuit is configured to: adopt a first state in which a determination of at least one indicator of the aging of the first circuit is performed by using the second circuit; then adopt a second state in which the first circuit is subjected to operating conditions causing aging; then adopt the first state again; compare the determined values of the indicator; and adapt the operation of the electronic circuit according to a result of the comparison.

This enables to measure in real time the progress of aging, whether under operating conditions or during accelerated tests.

Further, this enables to obtain the precise measurement of aging in circuit components such as transistors.

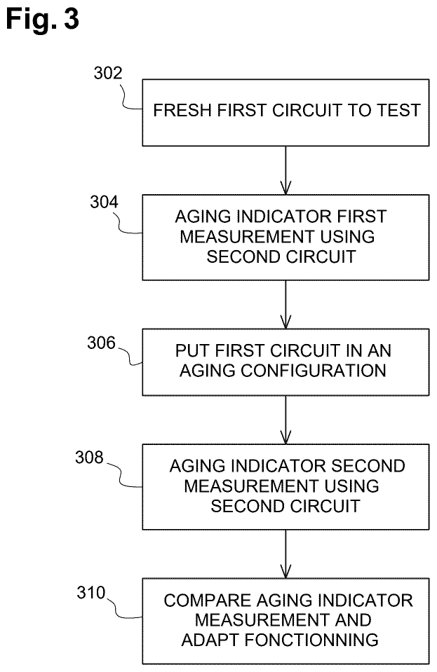

FIG. 3 shows an operating method of a circuit of FIG. 2 according to an embodiment. More particularly, FIG. 3 shows an operating method of circuit 102.

In this example, blocks 216 or 220 comprise a second circuit which is similar to a first circuit to be tested in the associated blocks, respectively blocks 218 and 219.

In the text, two components or sets of components or chains of components are similar when they are nominally identical to within manufacturing differences. For example, two similar components have the same dimensions, the same materials, or the same doping levels, to within manufacturing differences. In the case of transistors, two similar transistors must have the same gate width and length. Two similar components may have been designed to have the same dimensions or the same doping levels, for example, but after manufacturing, their dimensions or doping levels may slightly vary from one component to another, due to manufacturing processes that do not locally provide a strictly identical result.

A chain of components similar to another chain of components has identical components, to within manufacturing differences, with a same repeated pattern, to obtain a same physical implementation.

For example, the first circuit comprises a transistor or a chain of transistors of block 219, and the second circuit, which is coupled, preferably connected, to the first circuit, is integrated into block 220 and it comprises a transistor or a chain of transistors similar to that of the first circuit.

In another example, the first circuit comprises a chain of components of block 218, and the second circuit, which is coupled, preferably connected, to the first circuit, is integrated into block 216 and comprises a chain of components similar to that of the first circuit.

At a step 302 (FRESH FIRST CIRCUIT TO TEST), the first circuit has not been subjected to aging yet or has been subjected to non-destructive aging.

At a step 304 (AGING INDICATOR FIRST MEASUREMENT USING SECOND CIRCUIT), subsequent to step 302, circuit 102 adopts a first state in which the determination, or measurement, of one or plurality of indicators of aging of the first circuit is carried out by using the second circuit. In other words, a measurement of one or a plurality of indicators, such as a variation of the threshold voltage of transistors or such as a frequency variation of a chain of components, is performed on the second circuit, which is similar to the first circuit.

At a step 306 (PUT FIRST CIRCUIT IN AGING CONFIGURATION), subsequent to step 304, circuit 102 adopts a second state in which the first circuit is subjected to operating conditions causing aging.

In an example, which applies for example to block 220, in the second state, the second circuit is placed in a configuration where it is not subjected to aging. This enables to compare the aging indicators between the first circuit, which has been subjected to aging, and the second circuit, which has aging indicators that have not changed.

In another example, which for example applies to block 216, in the second state, the second circuit is placed in a configuration where it is subjected to the same aging as the first circuit. This enables to perform a measurement or a determination of one or a plurality of aging indicators on the second circuit without interrupting or disturbing the operation of the first circuit.

At a step 308 (AGING INDICATOR SECOND MEASUREMENT USING SECOND CIRCUIT), subsequent to step 306, circuit 102 adopts the first state again. In other words, step 304 is repeated.

In an example, which applies for example to block 220, this enables to compare the operation of the first circuit, which has been subjected to aging, and of the second circuit, which has remained preserved, and to deduce therefrom one or a plurality of indicators of the aging of the first circuit.

In another example, which for example applies to block 216, the second circuit is subjected to the same aging as the first circuit, then a measurement or a determination of one or a plurality of indicators of the aging of the second circuit will a priori provide a value similar to that of the first circuit. This measurement can thus be carried out without stopping, or disturbing, the operation of the first circuit.

At a step 310 (COMPARE AGING INDICATOR MEASUREMENTS AND ADAPT FUNCTIONNING), subsequent to step 310, by comparing the aging indicator(s), directly or indirectly, before and after aging, then aging control unit 214 can take measures to adapt the operating voltage or current or frequency of circuit 102 in order to preserve an operation of system 100 over time even if it has a lower performance.

A first aspect bears on a determination of a static parameter related to aging.

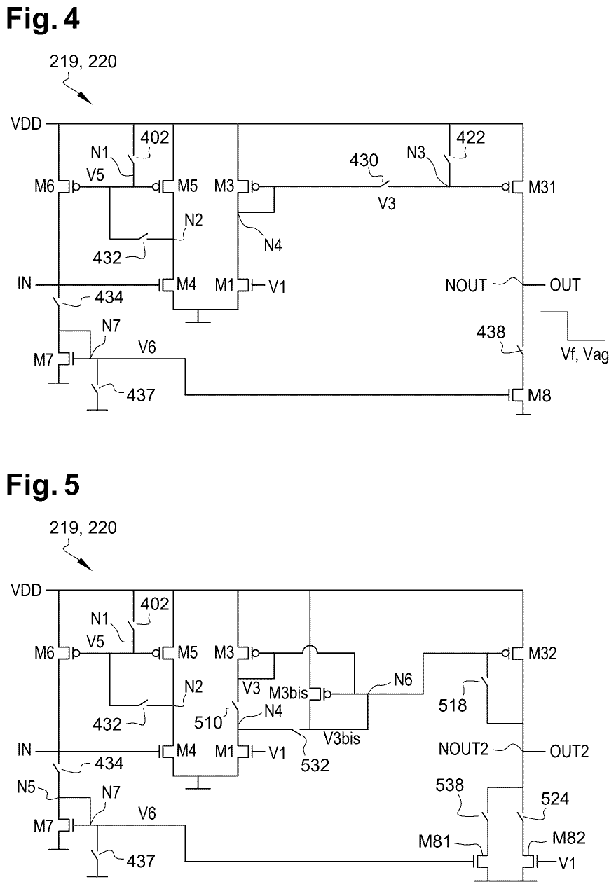

FIG. 4 shows an embodiment of blocks of FIG. 2. More particularly, FIG. 4 shows an example of blocks 220 and 219.

In the shown example, the transistor, the aging of which is to be known, is a transistor M1. The first circuit comprises transistor M1, of NMOS type for example, in series with transistor M3, of PMOS type. A conduction node of transistor M3 is coupled, preferably connected, to a first voltage rail configured to be set to a reference voltage VDD, otherwise known as Vdd_HV, for example greater than 7 V. A control node of transistor M3 is coupled, preferably connected, to the junction point N4 of transistors M1 and M3. A conduction node of transistor M1 is coupled, preferably connected, to ground.

In the shown example, the second circuit comprises a transistor M4, for example, of NMOS type, in series with a transistor M5, for example, of PMOS type. A conduction node of transistor M5 is configured to be coupled to voltage rail VDD. A control node N1 of transistor M5 is coupled, preferably connected, to the junction point N2 of transistors M5 and M4 via a switch 432. Transistor M4 has a conduction node coupled, preferably connected, to ground.

In an example, transistors M1 and M4 are paired, as well as transistors M3 and M5.

In the shown example, the second circuit comprises a transistor M6, of PMOS type for example, and having a conduction node configured to be coupled to first voltage rail VDD. The second circuit further comprises a transistor M7, of NMOS type for example, with a conduction node coupled to ground and another conduction node coupled, preferably connected, to its control node N7. The control node of transistor M6 is coupled, preferably connected, to the control node N1 of transistor M5. A switch 434 couples a conduction node of transistor M6 to node N7. In this example, a switch 402 couples the control node of transistor M5 to voltage rail VDD.

In the shown example, the second circuit comprises, for example, a transistor M31, of PMOS type and with a conduction node coupled to voltage rail VDD. The second circuit comprises a transistor M8, of NMOS type and having a conduction node coupled to ground. A switch 438 couples one conduction node of transistor M31 to another conduction node of transistor M8. A switch 430 couples the control nodes of transistor M3 and of transistor M31. A switch 422 couples the control node N3 of transistor M31 to voltage rail VDD, and a switch 437 couples ground to the control nodes N7 of transistors M7, M8.

In a non-illustrated example, a transistor M2 is mounted in a cascode assembly between transistor M1 and transistor M3. This cascode-mounted transistor protects transistor M1 from aging, but the combined M1+M2 structure is affected by aging.

The switches will enable to configure the circuit in test mode (first state) or in aging mode (second state). In the aging mode, in the example of FIG. 4, only transistors M1 and M3 are to age. In the first state, switches 434, 432, 438, and 430 are on, and switches 402, 437, 422 are off. Further, in the first state, the control node of transistor M4 is coupled to a third voltage rail configured to receive a voltage ramp IN, for example increasing and, for example, supplied by a digital-to-analog converter (DAC). In this first state, the control node of transistor M1 is coupled to the second voltage rail V1. In an example, voltage V1 is in the range from 0.5 to 1.5 V. In the first state, the first and second circuits form a comparator.

In the first state, by means of the voltage ramp applied to the control node of transistor M4, when voltage IN becomes equal to voltage V1 (to within differences of manufacturing of M4 with respect to M1), then the output voltage OUT at an output node of circuit NOUT, located between transistor M31 and switch 438, varies according to a square-wave pattern. The voltage value Vf of the voltage ramp, or the code of the digital-to-analog converter, which switches the comparator, is stored, for example, in a memory of a microcontroller.

In the second state, switches 434, 432, 438, 430 are off, and switches 402, 437, 422 are on. In this second state, the control node of transistor M4 is this time coupled to ground in order not to be subjected to aging, and the control node of transistor M1 is coupled to the second voltage rail V1. In this second state, transistor M1 operates normally in its functional application circuit, that is, it is subjected to aging, all the more as the voltage VDD is high.

After the first and second circuits have been placed in the first and second states, they are placed back in the first state. The new voltage value Vag of the voltage ramp, or the corresponding digital-to-analog converter code, which switches the comparator, is saved. If voltage Vag or its converter code differs from voltage Vf or its respective converter code, it is possible to deduce therefrom that aging has occurred in transistor M1, or in the M1+M2 structure if M2 is present, and to be able to quantify that aging. Indeed, the source-drain current through transistor M1 is dependent, whether in linear mode or saturation, on the threshold voltage.

In the shown example, the presence of transistor M3 may, however, induce inaccuracies in the measurement of the aging of transistor M1.

FIG. 5 shows an embodiment of a block of FIG. 2. More particularly, FIG. 5 shows an example of blocks 219 and 220.

The shown example comprises transistors M1, M3, M4, M5, M6, M7 and switches 402, 432, 434, and 437 arranged similarly to FIG. 4.

Additionally, the circuit of FIG. 5 comprises a switch 510 between the junction point N4 of transistors M3 and M1 and the conduction node of transistor M3 which is not coupled, or connected, to node VDD.

Further, the circuit of FIG. 5 comprises a transistor M32, of PMOS type for example, and having a first conduction node coupled to the first voltage rail. Its control node N6 is coupled to the control node of transistor M3, and its second conduction node is coupled, preferably connected, to an output node NOUT2 of the circuit. This second conduction node is coupled to control node N6 via a switch 518.

The circuit of FIG. 5 further comprises a transistor M82, of NMOS type for example, having a conduction node coupled, preferably connected, to ground, and another conduction node coupled, preferably connected, to output node NOUT2 via a switch 524. The control node of transistor M82 is configured to be coupled to the second voltage rail set to the second voltage V1.

The circuit of FIG. 5 comprises a transistor M81, of NMOS type for example, having a first conduction node coupled to ground, and having a second conduction node coupled to output node NOUT2 via a switch 538. The control node of transistor M81 is coupled to the control node of transistor M7.

In a non-illustrated example, the circuit of FIG. 5 comprises transistor 524 in a cascode assembly with transistor M1.

Optionally, the circuit of FIG. 5 comprises a transistor M3bis, of PMOS type for example, having a control node coupled, preferably connected, to the control node of transistor M32, a conduction node coupled to the first voltage rail VDD, and another conduction node coupled to the junction point N4 of transistors M1, M3 via a switch 512.

In operation, in the first state, switches 512, 518, 524 are off, and switches 510, 538 are on. In the second state, switches 512, 518, 524 are off, and switches 510, 538 are on.

The example of FIG. 5 enables to set transistors M3 and M32 in the same aging conditions. The variation in the value of the threshold voltage of transistor M3 no longer has any impact on the measurement of the aging of transistor M1.

In the shown example, transistor M82 is used for aging and transistor M81 is used for the first state, that is, for aging measurement. This enables to minimize the error in the measurement of the variation of the threshold voltage of M1.

Optionally, transistor M3 is is used during aging testing and transistor M3 is used for measurements. This enables to further minimize the error in the measurement of the variation of the threshold voltage of M1.

A second aspect bears on a determination of a dynamic parameter related to aging.

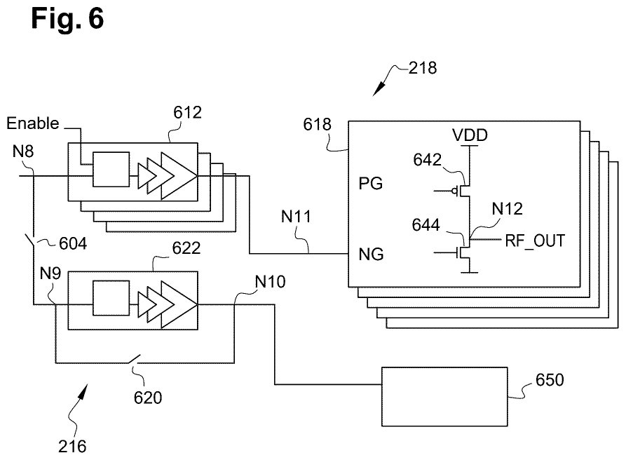

FIG. 6 shows an embodiment of a block of FIG. 2. More particularly, FIG. 6 shows an example of blocks 216 and 218.

In the shown example, block 218 comprises one or a plurality of selectable logical chains 612, each formed, for example, of inverters, or of buffer circuits, in series. In an example, the number of these inverters or buffer circuits is odd. One of the logical chains is selectable, for example, by a respective signal Enable.

In the example of FIG. 6, logical chain 612 connects an input node N8 of a signal, for example NFC, to be amplified, to node N11.

In the shown example, block 218 further comprises one or a plurality of circuits 618, each having a PMOS transistor 642 in series with an NMOS transistor 644 referenced to ground. A conduction node of PMOS transistor 642 is coupled, preferably connected, to reference voltage rail VDD, and a junction point N12 of transistors 642 and 644 corresponds to an output node of the amplified NFC signal RF_OUT. The control nodes of transistor 642 and of transistor 644 respectively receive a signal PG and NG in relation to the signal present on the node N11 of the respective logical chain 612.

Circuit 612 corresponds, for example, to the first circuit, the aging of which is desired to be known.

In the example of FIG. 6, circuit 216 comprises a circuit 622, corresponding for example to the second circuit, having a logical chain similar to at least one of the logical chains of circuit 612, the aging of which is desired to be known. An output node N10 of the logical chain of circuit 622 is coupled to an input node N9 of this same logical chain via a switch 620. In the case where the number of inverters or of buffer circuits is odd, this enables to form a ring oscillator when the switch is on.

In the shown example, the input node N8 of the logical chain of the first circuit is coupled to the input node N9 of the logical chain of circuit 622 via a switch 604. In this example, the output node N10 of the logical chain of circuit 622 is coupled to a load 650 having a value equivalent to that of the selected circuit 618. Load 650 is, however, another load, while being of same value, different from that of circuit 618 for reasons of operation of radio frequency circuit 618.

In the shown example, in the first state, switch 620 is on and switch 604 is off; and in the second state, switch 620 is off and switch 604 is on.

This enables to form, in the first state, a ring oscillator with circuit 622, and to determine a frequency or a time shift of this oscillator. The determination of the frequency or of the time shift is, for example, performed with a counter in comparison with a quartz oscillator clock frequency.

In the second state, circuit 622 is subjected to the same operating conditions as circuit 612, and since circuits 612 and 622 see the same load, this causes an equivalent aging. By determining the frequency or the time shift of the ring oscillator obtained with the second circuit, before and after aging, it is then possible to measure aging indicator, since the variation of the threshold voltage of transistors forming the inverters or buffers of circuit 622 influences their switching speed.

Various embodiments and variants have been described. Those skilled in the art will understand that certain features of these various embodiments and variants may be combined, and other variants will occur to those skilled in the art. In particular, in the examples of FIGS. 4 and 5, those skilled in the art may change the NMOS transistors to PMOS transistors, and vice versa, by inverting voltages VDD, IN, and V1.

Finally, the practical implementation of the described embodiments and variants is within the abilities of those skilled in the art based on the functional indications given hereabove. In particular, regarding the logical chains of circuits 612 and 622, it is possible to envisage components other than inverters or buffer circuits in series.

1. An electronic circuit, comprising:
a first circuit to be tested; and
a second circuit coupled to the first circuit and having at least components similar to those of the first circuit;
wherein the electronic circuit is configured to:
adopt a first state in which a determination of at least one indicator of aging of the first circuit is performed by measuring a value of the at least one indicator of aging using an aging indicator of the second circuit;
then adopt a second state in which the first circuit is subjected to operating conditions causing aging;
then adopt the first state again;
compare determined values of the at least one indicator of aging; and
adapt operation of the electronic circuit according to a result of the comparison.

2. The electronic circuit according to claim 1, wherein adapting operation of the electronic circuit in response to the comparison indicating aging of the first circuit, comprises lowering performances of the electronic circuit.

3. The electronic circuit according to claim 1, wherein the first and second circuits each comprise at least one transistor, and wherein said indicator of aging is a threshold voltage of said at least one transistor.

4. The electronic circuit according to claim 1, wherein, in the second state, the second circuit is not subjected to said operating conditions causing aging.

5. The electronic circuit according to claim 1, wherein:
the first circuit comprises a first transistor of NMOS type in series with a second transistor of PMOS type, a first conduction node of the second transistor configured to be coupled to a first voltage rail set to a first reference voltage, a control node of the second transistor connected to the junction point of the first and second transistors;
the second circuit comprises a third transistor of NMOS type in series with a fourth transistor of PMOS type, a conduction node of the fourth transistor configured to be coupled to the first voltage rail; and
the first and third transistors each have a conduction node coupled to ground.

6. The electronic circuit according to claim 5, wherein the first and third transistors are paired and wherein the second and fourth transistors are paired.

7. The electronic circuit according to claim 5, wherein the second circuit comprises:
a fifth transistor of PMOS type and having a conduction node configured to be coupled to the first voltage rail; and
a sixth transistor of NMOS type with a conduction node coupled to ground and another conduction node coupled to its control node, the control node of the fifth transistor connected to the control node of the fourth transistor, a first switch coupling a conduction node of the fifth transistor to a conduction node of the sixth transistor, a second switch coupling the control node of the fourth transistor to the junction point of the third and fourth transistors, a third switch coupling the control node of the fourth transistor to the first voltage rail.

8. The electronic circuit according to claim 7, wherein the second circuit comprises:
a seventh transistor of PMOS type and having a conduction node configured to be coupled to the first voltage rail; and
an eighth transistor of NMOS type and having a conduction node coupled to ground, a fourth switch coupling a conduction node of the seventh transistor to a conduction node of the eighth transistor, a fifth switch coupling ground to the control node of the sixth and eighth transistors, a sixth switch coupling the control nodes of the second and seventh transistors, a seventh switch coupling the control node of the seventh transistor to the first voltage rail.

9. The electronic circuit according to claim 8, wherein a ninth transistor is mounted in a cascode assembly to the first transistor.

10. The electronic circuit according to claim 8, wherein:
in the first state, the first and second switches are on, and the third and fifth switches are off, the control node of the third transistor is coupled to a third voltage rail configured to receive a voltage ramp, and the control node of the first transistor is coupled to the second voltage rail; and
in the second state, the first and second switches are off, and the third and fifth switches are on, the control node of the third transistor is coupled to ground and the control node of the first transistor is coupled to the second voltage rail.

11. The electronic circuit according to claim 10, wherein:
in the first state, the fourth and sixth switches are on, and the seventh switch is off; and
in the second state, the fourth and sixth switches are off, and the seventh switch is on.

12. The electronic circuit according to claim 7, wherein the second circuit comprises:
a tenth transistor of PMOS type having a first conduction node coupled to the first voltage rail, having a control node coupled to the control node of the second transistor, and having a second conduction node coupled to its control node via an eighth switch;
an eleventh transistor of NMOS type having a conduction node coupled to ground, another conduction node coupled to the second conduction node of the eleventh transistor via a ninth switch, and a control node configured to be coupled to a second voltage rail set to a second voltage; and
a twelfth transistor of NMOS type having a first conduction node coupled to ground, having a second conduction node coupled to the second conduction node of the tenth transistor via a tenth switch, and having a control node coupled to the control node of the sixth transistor.

13. The electronic circuit according to the claim 12, wherein the second circuit comprises:
a thirteenth transistor of PMOS type having a control node coupled to the control node of the eleventh transistor, a conduction node coupled to the first voltage rail, and another conduction node coupled to the junction point of the first and second transistors via an eleventh switch; and
a twelfth switch coupling the junction point of the first and second transistors and a second conduction node of the second transistor.

14. The electronic circuit according to claim 13, wherein:
in the first state, the eleventh switch is off, and the twelfth switch is on, and
in the second state, the eleventh switch is on, and the twelfth switch is off.

15. The electronic circuit according to claim 12, wherein: in the first state, the eighth and ninth switches are off, and the tenth switch is on, and in the second state, the eighth and ninth switches are on, and the tenth switch is off.

16. The electronic circuit according to claim 1, wherein, in the second state, the second circuit is also subjected to said operating conditions causing aging.

17. The electronic circuit according to claim 16, wherein:
the first and second circuits each comprise a similar logical chain;
an output node of the logical chain of the second circuit is coupled to an input node of this same logical chain via a thirteenth switch so as to form a ring oscillator when the thirteenth switch is on;
an input node of the logical chain of the first circuit is coupled to the input node of the logical chain of the second circuit via a fourteenth switch; and
the output node of the logical chain of the second circuit and an output node of the logical chain of the first circuit are coupled to a different load of equivalent value.

18. The electronic circuit according to claim 17, wherein the logical chain of the first and second circuits comprises an odd number of inverters, or of buffer circuits, in series.

19. The electronic circuit according to claim 17, wherein said at least one indicator of aging is a frequency or a time shift of the ring oscillator.

20. The electronic circuit according to claim 17, wherein:
in the first state, thirteenth switch is on and fourteenth switch is off; and
in the second state, thirteenth switch is off and fourteenth switch is on.

21. An operating method of an electronic circuit that includes a first circuit to be tested and a second circuit similar to the first circuit and coupled to the first circuit, the method comprising the following steps:
placing the electronic circuit in a first state where a determination of at least one indicator of aging of the first circuit is performed by measuring a value of the at least one indicator of aging using an aging indicator of the second circuit;
then placing the electronic circuit in a second state in which the first circuit is subjected to operating conditions causing aging;
then placing the electronic circuit back in the first state;
comparing the determined values of the at least one indicator of aging; and
adapting the operation of the electronic circuit according to a result of the comparison.

22. The method of use of the electronic circuit according to claims 21, further comprising using the second circuit to determine the aging of the first circuit and adapting the operation of the electronic circuit as a function of the determined aging.

23. The method according to claim 21, wherein, if the comparison indicates aging of the first circuit, then lowering performance of the electronic circuit.

24. The method according to claim 21, wherein said at least one indicator of aging is a threshold voltage of at least one transistor the first and second circuits.

25. The method according to claim 21, wherein, in the second state, the second circuit is not subjected to said operating conditions causing aging.
